(19) United States
(12) Patent Application Publication
(10) Pub. No.: US 2026/0226606 A1
(43) Pub. Date: Aug. 6, 2026

(54) MAX-Ag ELECTRICALLY CONDUCTIVE COMPOSITE COATING AND PREPARATION METHOD THEREOF

(71) Applicant: NINGBO INSTITUTE OF MATERIALS TECHNOLOGY AND ENGINEERING, CHINESE ACADEMY OF SCIENCES, Ningbo (CN)

(72) Inventors: Aiying WANG, Ningbo (CN); Zhenyu WANG, Ningbo (CN); Guanshui MA, Ningbo (CN); Li WANG, Ningbo (CN)

(21) Appl. No.: 19/150,748

(22) PCT Filed: Apr. 16, 2024
(86) PCT No.: PCT/CN2024/087854

§ 371 Date: Jul. 24, 2025

(30) Foreign Application Priority Data
Jul. 18, 2023 (CN) 202310880800.6

(51) Int. Cl. C23C 14/35; C23C 14/02; C23C 14/06; C23C 14/34; C23C 28/04

(52) U.S. Cl. CPC C23C 14/35; C23C 14/021; C23C 14/028; C23C 14/0635; C23C 14/0641; C23C 14/3485; C23C 28/042

(57) ABSTRACT

Disclosed a MAX-Ag electrically conductive composite coating and a preparation method thereof. The electrically conductive composite coating comprises a MAX phase and an Ag phase. The chemical formula of the MAX phase is Mₙ₊₁AXₙ, where M is a transition metal element, A is an Al element, X is a C or N element, and n is an integer of 1 to 3. The MAX phase is in a lath-like structure, the Ag phase is in a nano-twinned structure, and the Ag phase is aggregated at a grain boundary of the MAX phase. The electrically conductive composite coating as a whole is in an Ag-wrapped MAX phase structure. In the present disclosure, a grain shape heterogeneous design is performed on the MAX phase coating by Ag element doping. The Ag doping affects the growth of the MAX phase grain, so that the MAX phase grain is in a lath-like structure.

### TECHNICAL FIELD

The present disclosure relates to the technical field of surface engineering, and in particular to a MAX-Ag electrically conductive composite coating and a preparation method thereof.

### BACKGROUND

With the pursuit of large-scale, long-range and lightweight aerospace technology, the application of composite materials is becoming increasingly extensive. However, because composite materials themselves are poor conductors, it is difficult to dissipate the current attached to the materials in a short time during the lightning strike. However, for spacecraft, the current demand for all-weather launches is increasing day by day, and there are limitations in the way of selecting launch windows to avoid lightning weather. The destructive effects of lightning have many aspects, such as machinery, environment and arc. Examples include insulation breakdown, phase change, combustion, melting erosion and structural distortion caused by arcs, and the adverse effects of electromagnetic field coupling on electronic and electrical equipment. Therefore, the demand for conductive protective coating on its surface is becoming increasingly urgent, and the reliability requirements are also getting higher and higher.

MAX phase is a type of hexagonal close-packed ternary layered compound. Its unique structure enables it to have the excellent properties of both metal materials and ceramic materials, such as high thermal conductivity, processability and plasticity similar to metal materials, or high strength, high melting point, good thermal stability and oxidation resistance similar to ceramic materials. Recent studies have shown that MAX as a coating material has shown very good application prospects in the fields of fuel cell bipolar plate, electromagnetic shielding and wave absorption, aerospace, etc. MAX phase has moderate thermal stability. In the process of arc discharge, the integrity of the composition and structure of the MAX phase can be guaranteed at 1400° C. or below; and the MAX phase has a tendency to slowly decompose and oxidize at above 1400° C. Therefore, there is no defects of premature loss and late residue in the MAX phase during arc erosion. At the same time, the MAX phase has high thermal conductivity, which is conducive to surface heat dissipation and avoids serious heat accumulation.

The resistivity of the MAX phase is higher than that of pure metal, and Ag has the best electrical conductivity among all metals. Applying Ag as a composite element to the coating can increase its electrical conductivity. For example, a preparation method of a MAX-Ag phase composite coating disclosed in patent CN115896726A adopts magnetron sputtering composite cathode arc technology to deposit a Cr—Al—C—Ag coating on the surface of a substrate, and then performs annealing treatment to obtain a Cr₂AlC—Ag composite coating, the coating has a composite structure of MAX phase and AlAg₃, wherein the grains of the MAX phase are equiaxed structures, and the Ag element is evenly distributed in the coating without forming a new conductive path. The resistivity of the composite coating is still far behind that of pure metal, and higher requirements are placed on the electrical conductivity of the coating in the field of electrical contact in aerospace technology.

### SUMMARY

In view of the deficiencies of the existing technology, the technical problem to be solved by the present disclosure is how to reduce the resistivity and improve the electrical conductivity property of the MAX-Ag composite coating.

To achieve the above object, the present disclosure provides a MAX-Ag electrically conductive composite coating, wherein the electrically conductive composite coating comprises a MAX phase and an Ag phase, the chemical formula of the MAX phase is Mₙ₊₁AXₙ, wherein M is a transition metal element, A is an Al element, X is a C or N element, and n is an integer of 1 to 3, the MAX phase is in a lath-like structure, the Ag phase is in a nano-twinned structure, the Ag phase is aggregated at a grain boundary of the MAX phase, the electrically conductive composite coating as a whole is in an Ag-wrapped MAX phase structure.

In the present disclosure, a grain shape heterogeneous design is performed on the MAX phase coating by Ag element doping. The Ag doping affects the growth of the MAX phase grain, so that the MAX phase grain is in a lath-like structure. At the same time, the doped Ag is in a nano-twinned structure and fully wraps the MAX phase grains. Ag is continuously distributed at the MAX grain boundary. This special structure can effectively reduce the scattering of electrons, provide a strong conductive path, and give the coating excellent electrical conductivity property.

Furthermore, the MAX phase has a grain width of 10-90 nm and a grain length of 25-300 nm. In the present disclosure, the restrictive relationship between the strength and electrical conductivity is broken through by the grain shape heterogeneous design, thereby improving the strength and electrical conductivity of the coating.

Furthermore, the MAX phase has a grain aspect ratio of between 2 and 7. The grain width mainly affects the strength, and the grain length mainly affects the electrical conductivity. When the aspect ratio is between 2 and 7, the comprehensive performance of the strength and electrical conductivity of the coating is the best.

Furthermore, the Ag phase aggregated at the grain boundary of the MAX phase has a thickness of 1 to 20 nm. As the thickness of the Ag phase increases, the electrical conductivity property of the corresponding coating is good, but when the thickness of the Ag phase is greater than 20 nm, the strength of the coating will decrease rapidly.

Furthermore, the MAX phase is selected from Cr₂AlC, Cr₂AlN, Ti₂AlC, Ti₂AlN, and Zr₂AlC. This special structure is applicable to a variety of MAX phase coatings. The electrical conductivity property of the MAX-Ag electrically conductive composite coating can be increased by more than 2 times compared with the pure MAX coating.

Furthermore, the Ag content in the electrically conductive composite coating is 1-10 at. %. The content of Ag element required in the coating is less, which has a significant silver-saving effect, and reduces material costs. In addition, the Ag element affects the mutual diffusion of elements in the coating. Thus, too high Ag element content is not conducive to the formation of MAX phase.

The present disclosure also provides a preparation method of the above MAX-Ag electrically conductive composite coating, comprising the following steps:
S1. providing a substrate, and sequentially performing mechanical polishing, ultrasonic cleaning and glow cleaning on the substrate;
S2. placing the substrate in a vacuum chamber, using a simple substance target of M element as an arc target, introducing a reaction gas for providing X element and an inert gas, and depositing an M-X layer by an arc ion plating technology;
S3. using the composite target of A element and Ag as a DC pulsed magnetron sputtering target, and depositing an A-Ag-X layer by the magnetron sputtering technology;
S4. repeating the steps S2 and S3 for 2 to 20 times to form an M—X/A—Ag—X alternately laminated coating;
S5. performing vacuum heat treatment on the alternately laminated coating obtained in the step S4 to obtain a MAX-Ag electrically conductive composite coating.

In the present disclosure, the M—X layer and the A—Ag—X layer are alternately deposited by the arc ion plating technology and the magnetron sputtering technology, so as to obtain the coating with the alternately laminated structure, and then the vacuum heat treatment is performed, so that the Ag affects the growth process of the MAX phase grain, the original equiaxial MAX phase grain is converted into the MAX phase grain in a lath shape, and at the same time, the Ag is distributed at the grain boundary of the MAX phase in a nano-twinned structure, so as to form a new conductive path. The alternately laminated structure enables the coating to form this special structure as a whole, while maintaining the uniformity of the overall composition of the coating, ensuring the strength and avoiding the formation of defects.

Furthermore, in the step S2, the substrate has a bias voltage of (−50)-(−200) V, the target-to-substrate distance between the substrate and the cathode arc target is 15-20 cm, the cathode arc target has a power of 1-3 kW and a current of 30-70 A, the reaction gas is introduced at a flow rate of 15-30 sccm, the inert gas is introduced at a flow rate of 150-200 sccm, and the deposition time is 5-30 min.

Further, in the step S3, the substrate has a bias voltage of (−50)-(−200) V, the target-to-substrate distance between the substrate and the DC pulsed magnetron sputtering target is 10-15 cm, the DC pulsed magnetron sputtering target has a power of 2-3.5 kW, the reaction gas is introduced at a flow rate of 15-30 sccm, the inert gas is introduced at a flow rate of 150-200 sccm, and the deposition time is 5-30 min.

In the present disclosure, the composition of the elements in the coating are controlled by controlling the gas flow rate and the coating parameters, and the coating thickness is controlled by the deposition time. The prepared MAX-Ag electrically conductive composite coating has good uniformity, fine grains inside the coating, and less crystal defects.

Furthermore, in the step S5, in the vacuum heat treatment, the vacuum degree is less than 2.0×10⁻³ Torr, the temperature is 500-750° C., and the time is 30-360 min. In the process of the vacuum heat treatment, lath-like MAX phase grains are formed, and the electrically conductive composite coating as a whole is in an Ag-wrapped MAX phase structure.

In summary, compared with the existing technology, the present disclosure has the following beneficial effects:
(1) In the MAX-Ag electrically conductive composite coating obtained by the present disclosure, a grain shape heterogeneous design is performed on the MAX phase coating by Ag element doping, so that the MAX-Ag phase grains are in a lath-like structure; At the same time, the doped Ag is in a nano-twinned structure and fully wraps the MAX phase grains. This special structure can effectively reduce the scattering of electrons, provide a strong conductive path, and give the coating excellent electrical conductivity property.
(2) In the present disclosure, the coating with an alternately laminated structure is prepared first to form an M—X/A—Ag—X alternately laminated coating. During the annealing process, the elements diffuse to generate the MAX phase grains. Ag affects the growth of the MAX phase grains, so that the original equiaxed MAX phase grains are converted into lath-like MAX phase grains. The coating can form a special structure of the Ag-wrapped MAX phase as a whole, while maintaining the uniformity of the overall composition of the coating, ensuring the strength and avoiding the formation of defects
(3) In the present disclosure, the thickness of the coating is accurately controlled by controlling the coating time. The prepared MAX-Ag electrically conductive composite coating has good uniformity, fine grains inside the coating, and less crystal defects. The electrical conductivity property of the MAX-Ag composite coating is more than 2 times that of the pure MAX coating. Therefore, the current dissipation speed is improved to realize protection of the substrate. The coating has a wide application prospect in the fields of electrical contact and the like.

### BRIEF DESCRIPTION OF THE DRAWINGS

FIG. 1 is a transmission electron microscope image of the coatings prepared in Example 1 and Comparative Example 1 of the present disclosure.

FIG. 2 is a schematic diagram showing the microstructures of the coatings prepared in Example 1 and Comparative Example 1 of the present disclosure.

FIG. 3 is a graph showing the XPS test results of the coatings prepared in Example 1 and Comparative Example 1 of the present disclosure.

FIG. 4 is a graph showing the resistivity performance test results of the coatings prepared in Example 1 and Comparative Example 1 of the present disclosure.

### DETAILED DESCRIPTION OF THE EMBODIMENTS

In order to make the above-mentioned objects, features and advantages of the present disclosure more obvious and easy to understand, specific embodiments of the present disclosure are described in detail below with reference to the accompanying drawings.

It should be understood that the terms described in the present disclosure are merely intended to describe special embodiments, and are not intended to limit the present disclosure. In addition, for the numerical range in the present disclosure, it should be understood that each intermediate value between the upper and lower limits of the range is also specifically disclosed. Each smaller range between any stated value or intermediate value within the stated range, as well as any other stated value or intermediate value within the stated range is also included within the present disclosure. The upper and lower limits of these smaller ranges can independently be included or excluded from the range.

It is obvious to those skilled in the art that various modifications and changes can be made to the specific embodiments in the specification of the present disclosure without departing from the scope or spirit of the present disclosure. Other embodiments obtained in accordance with the specification of the present disclosure are obvious to those skilled in the art.

A specific embodiment of the present disclosure provides a MAX-Ag electrically conductive composite coating, wherein the electrically conductive composite coating comprises a MAX phase and an Ag phase, and the overall thickness of the coating is 10-100 μm.

The chemical formula of the MAX phase is Mₙ₊₁AXₙ, wherein M is a transition metal element, A is an Al element, X is a C or N element, and n is an integer of 1 to 3. The MAX phase specifically includes Cr₂AlC, Cr₂AlN, Ti₂AlC, Ti₃AlC₂, Ti₄AlC₃, Ti₂AlN, Zr₂AlC and the like.

A grain shape heterogeneous design is performed on the MAX phase coating by Ag element doping. The Ag doping affects the growth of the MAX phase grain, so that the MAX phase grain is in a lath-like structure, and the MAX phase have a grain width of 10-90 nm and a length of 25-300 nm. Preferably, the grain aspect ratio of the MAX phase is between 2 and 7. The restrictive relationship between the strength and electrical conductivity is broken through by the grain shape heterogeneous design, thereby improving the strength and electrical conductivity of the coating.

The Ag phase is in a nano-twinned structure, and the Ag phase is aggregated at a grain boundary of the MAX phase. The electrically conductive composite coating as a whole is in an Ag-wrapped MAX phase structure. Ag is continuously distributed at the MAX grain boundary, thereby forming a new conductive path, and giving the coating excellent electrical conductivity property. Preferably, the thickness of the Ag phase is 1-20 nm, so that the strength and electrical conductivity performances of the coating are ensured to be excellent.

The Ag content in the electrically conductive composite coating is relatively low, generally 1-10 at. %. The content of Ag element required in the coating is relatively low, and thus the silver-saving effect is obvious. Too high content of Ag element is not conducive to the formation of the MAX phase.

The preparation method of the above-mentioned MAX-Ag electrically conductive composite coating comprises the following steps:
S1. providing a substrate, and sequentially performing mechanical polishing, ultrasonic cleaning and glow cleaning on the substrate.

In a specific embodiment, the substrate can be any one or a combination of two or more selected from pure titanium, titanium alloy, stainless steel, red copper, aluminum oxide, and carbon fiber composite material.

The working conditions of the glow cleaning are as follows: the working atmosphere is argon with a flow rate of 30-50 sccm, the vacuum degree during sputtering is 2.0×10⁻⁵−4.0×10⁻⁵ Torr, the substrate is preheated to 100-300° C., the bias voltage of the deposition is (−100)-(−250) V, the current of the linear anode ion source is set to 0.2 A, and the glow cleaning time of the substrate is 20-60 min.
S2. placing the substrate in a vacuum chamber, using a simple substance target of M element as an arc target, introducing a reaction gas for providing X element and an inert gas, and depositing an M-X layer by an arc ion plating technology.

In a specific implementation, the substrate is preheated to 100-300° C., the substrate has a bias voltage of (−50)-(−200) V, the target-to-substrate distance between the substrate and the cathode arc target is 15-20 cm, the cathode arc target has a power of 1-3 kW and a current of 30-70 A, the reaction gas is introduced at a flow rate of 15-30 sccm, the inert gas is introduced at a flow rate of 150-200 sccm, and the deposition time is 5-30 min. The composition of each element in the coating can be adjusted by controlling the gas flow rate and the coating parameters, and the thickness of the coating can be controlled by adjusting the deposition time.
S3. using the composite target of A element and Ag as a DC pulsed magnetron sputtering target, and depositing an A—Ag—X layer by the magnetron sputtering technology.

In a specific implementation, the substrate has a bias voltage of (−50)-(−200) V, the target-to-substrate distance between the substrate and the DC pulsed magnetron sputtering target is 10-15 cm, the DC pulsed magnetron sputtering target has a power of 2-3.5 kW, the reaction gas is introduced at a flow rate of 15-30 sccm, the inert gas is introduced at a flow rate of 150-200 sccm, and the deposition time is 5-30 min. The composition of each element in the coating can be adjusted by controlling the gas flow rate and the coating parameters, and the thickness of the coating can be controlled by adjusting the deposition time.
S4. repeating the steps S2 and S3 for 2 to 20 times to form an M-X/A—Ag—X alternately laminated coating.
S5. performing vacuum heat treatment on the alternately laminated coating obtained in the step S4 to obtain a MAX-Ag electrically conductive composite coating.

In a specific embodiment, in vacuum heat treatment, the vacuum degree is less than 2.0×10⁻³ Torr, the temperature is 500-750° C., and the time is 30-360 min. During the vacuum heat treatment, lath-like MAX phase grains are formed, and the electrically conductive composite coating as a whole is in an Ag-wrapped MAX phase structure. During the vacuum heat treatment, the MAX phase nucleates and grows. During the growth process, the presence of Ag has an inhibitory effect on its growth, so the grain growth will be parallel to the direction of Ag, forming lath-like MAX grains. At the same time, the diffusion rate of Ag is high, but Ag does not react with the MAX phase, and finally forms a non-reactive interface and wraps the MAX phase grains. The alternately laminated structure enables the coating to form this special structure as a whole, while maintaining the uniformity of the overall composition of the coating, ensuring strength, and avoiding the formation of defects.

The technical effects of the present disclosure will be described below in conjunction with specific examples.

### Example 1

In this example, the substrate was an aluminum oxide substrate, and the preparation method of the Cr—Al—C-based MAX phase-Ag composite coating on the surface of the substrate was as follows:
(1) The cleaned, oil-removed and dried substrate was put into the cavity. When the vacuum pressure in the cavity was below 3.0×10⁻⁵ Torr, 33.4 sccm of Ar gas was introduced into the vacuum chamber, the current of the linear anode ion source was set to 0.2 A, the bias voltage of the substrate was set to −200 V, and the ionized argon ion was used to etch the substrate for 30 min.
(2) An Cr—C layer was deposited by arc ion plating technology. In 200 sccm of an Ar protective atmosphere, the temperature was 150° C. A simple substance target of Cr element was mounted on the arc source as a Cr source. The power of the target was 1.0 kW, and the current of the target was 60 A. The bias voltage of the substrate was set to −150 V, 25 sccm of CH₄ was introduced, the pressure in the chamber was controlled to be 20 mTorr, and deposition was carried out for 10 min. During the deposition of the coating, the substrate rotated at a constant speed in the chamber to obtain an as-deposited Cr—C layer.
(3) An Al—Ag—C layer was deposited by magnetron sputtering technology. In 200 sccm of an Ar protective atmosphere, the temperature was 150° C., the magnetron source was an AlAg (5 at. % Ag) target, the power of the target was 3.1 kW, and the current of the target was 7.0 A. The bias voltage of the substrate was set to −150 V, 25 sccm of CH₄ was introduced, the gas pressure in the chamber was controlled to be 20 mTorr, and the deposition was carried out for 10 min. During the deposition of the coating, the substrate rotated at a constant speed in the chamber to obtain an as-deposited Al—Ag—C layer.
(4) The steps (2) and (3) were repeated 6 times to prepare an alternately laminated coating having 6 layers of Cr—C/Al—Ag—C.
(5) The Cr—C/Al—Ag—C alternately laminated coating was placed in an annealing furnace, and kept at 700° C. for 120 min in an environment where a vacuum degree was less than 3.0×10⁻⁵ Torr, to obtain a Cr₂AlC—Ag composite coating.

### Example 2

In this example, the substrate was a carbon fiber composite substrate, and the preparation method of the Cr—Al—C-based MAX phase-Ag composite coating on the surface of the substrate was as follows:
(1) The cleaned, oil-removed and dried substrate was put into the cavity. When the vacuum pressure in the cavity was below 2.0×10⁻⁵ Torr, 35 sccm of Ar gas was introduced into the vacuum chamber, the current of the linear anode ion source was set to 0.2 A, the bias voltage of the substrate was set to −100 V, and the ionized argon ion was used to etch the substrate for 40 min.
(2) An Cr—C layer was deposited by arc ion plating technology. In 150 sccm of an Ar protective atmosphere, the temperature was 200° C. A simple substance target of Cr element was mounted on the arc source as a Cr source. The power of the target was 2.5 kW, and the current of the target was 50 A. The bias voltage of the substrate was set to −100 V, 20 sccm of CH₄ was introduced, the pressure in the chamber was controlled to be 20 mTorr, and deposition was carried out for 15 min. During the deposition of the coating, the substrate rotated at a constant speed in the chamber to obtain an as-deposited Cr—C layer.
(3) An Al—Ag—C layer was deposited by magnetron sputtering technology. In 150 sccm of an Ar protective atmosphere, the temperature was 200° C., the magnetron source was an AlAg (2 at. % Ag) target, the power of the target was 2.8 kW, and the current of the target was 6 A. The bias voltage of the substrate was set to −100 V, 20 sccm of CH₄ was introduced, the gas pressure in the chamber was controlled to be 20 mTorr, and the deposition was carried out for 15 min. During the deposition of the coating, the substrate rotated at a constant speed in the chamber to obtain an as-deposited Al—Ag—C layer.
(4) The steps (2) and (3) were repeated 8 times to prepare an alternately laminated coating having 8 layers of Cr—C/Al—Ag—C.
(5) The Cr—C/Al—Ag—C alternately laminated coating was placed in an annealing furnace, and kept at 650° C. for 200 min in an environment where a vacuum degree was less than 2.0×10⁻⁵ Torr, to obtain a Cr₂AlC—Ag composite coating.

### Example 3

In this embodiment, the substrate was a stainless steel substrate, and the preparation method of the Cr—Al—N-based MAX phase-Ag composite coating on the surface of the substrate was as follows:
(1) The cleaned, oil-removed and dried substrate was put into the cavity. When the vacuum pressure in the cavity was below 3.0×10⁻⁵ Torr, 40 sccm of Ar gas was introduced into the vacuum chamber, the current of the linear anode ion source was set to 0.2 A, the bias voltage of the substrate was set to −200 V, and the ionized argon ion was used to etch the substrate for 20 min.
(2) An Cr—N layer was deposited by arc ion plating technology. In 150 sccm of an Ar protective atmosphere, the temperature was 200° C. A simple substance target of Cr element was mounted on the arc source as a Cr source. The power of the target was 2 kW, and the current of the target was 70 A. The bias voltage of the substrate was set to −200 V, 15 sccm of N₂ was introduced, the pressure in the chamber was controlled to be 20 mTorr, and the deposition was carried out for 20 min. During the deposition of the coating, the substrate rotated at a constant speed in the chamber to obtain an as-deposited Cr—N layer.
(3) An Al—Ag—N layer was deposited by magnetron sputtering technology. In 150 sccm of an Ar protective atmosphere, the temperature was 200° C., the magnetron source was an AlAg (6 at. % Ag) target, the power of the target was 2.5 kW, and the current of the target was 5 A. The bias voltage of the substrate was set to −200 V, 15 sccm of N₂ was introduced, the gas pressure in the chamber was controlled to be 20 mTorr, and the deposition was carried out for 20 min. During the deposition of the coating, the substrate rotated at a constant speed in the chamber to obtain an as-deposited Al—Ag—N layer.
(4) The steps (2) and (3) were repeated 5 times to prepare an alternately laminated coating having 5 layers of Cr—N/Al—Ag—N.
(5) The Cr—N/Al—Ag—N alternately laminated coating was placed in an annealing furnace, and kept at 750° C. for 60 min in an environment where a vacuum degree was less than 2.0×10⁻⁵ Torr, to obtain a Cr₂AlN—Ag composite coating.

### Example 4

In this example, the substrate was a titanium alloy substrate, and the preparation method of the Ti—Al—C-based MAX phase-Ag composite coating on the surface of the substrate was as follows:
(1) The cleaned, oil-removed and dried substrate was put into the cavity. When the vacuum pressure in the cavity was below 2.0×10⁻⁵ Torr, 50 sccm of Ar gas was introduced into the vacuum chamber, the current of the linear anode ion source was set to 0.2 A, the bias voltage of the substrate was set to −50 V, and the ionized argon ion was used to etch the substrate for 60 min.
(2) An Ti—C layer was deposited by arc ion plating technology. In 180 sccm of an Ar protective atmosphere, the temperature was 250° C. A simple substance target of Ti element was mounted on the arc source as a Ti source. The power of the target was 2.8 kW, and the current of the target was 65 A. The bias voltage of the substrate was set to −180 V, 20 sccm of CH 4 was introduced, the pressure in the chamber was controlled to be 20 mTorr, and the deposition was carried out for 25 min. During the deposition of the coating, the substrate rotated at a constant speed in the chamber to obtain an as-deposited Ti—C layer.
(3) An Al—Ag—C layer was deposited by magnetron sputtering technology. In 180 sccm of an Ar protective atmosphere, the temperature was 250° C., the magnetron source was an AlAg (6 at. % Ag) target, the power of the target was 3.2 kW, and the current of the target was 8 A. The bias voltage of the substrate was set to −200 V, 25 sccm of CH₄ was introduced, the gas pressure in the chamber was controlled to be 20 mTorr, and the deposition was carried out for 25 min. During the deposition of the coating, the substrate rotated at a constant speed in the chamber to obtain an as-deposited Al—Ag—C layer.
(4) The steps (2) and (3) were repeated 3 times to prepare an alternately laminated coating having 3 layers of Ti—C/Al—Ag—C.
(5) The Ti—C/Al—Ag—C alternately laminated coating was placed in an annealing furnace, and kept at 700° C. for 150 min in an environment where a vacuum degree was less than 2.0×10⁻⁵ Torr, to obtain a Ti₂AlC—Ag composite coating.

### Example 5

In this example, the substrate was a red copper substrate, and the preparation method of the Zr—Al—C-based MAX phase-Ag composite coating on the surface of the substrate was as follows:
(1) The cleaned, oil-removed and dried substrate was put into the cavity. When the vacuum pressure in the cavity was below 2.5×10⁻⁵ Torr, 30 sccm of Ar gas was introduced into the vacuum chamber, the current of the linear anode ion source was set to 0.2 A, the bias voltage of the substrate was set to −100 V, and the ionized argon ion was used to etch the substrate for 50 min.
(2) A Zr—C layer was deposited by arc ion plating technology. In 150 sccm of an Ar protective atmosphere, the temperature was 100° C. A simple substance target of Zr element was mounted on the arc source as a Zr source. The power of the target was 2 kW, and the current of the target was 50 A. The bias voltage of the substrate was set to −100 V, 20 sccm of CH₄ was introduced, the pressure in the chamber was controlled to be 20 mTorr, and the deposition was carried out for 10 min. During the deposition of the coating, the substrate rotated at a constant speed in the chamber to obtain an as-deposited Zr—C layer.
(3) An Al—Ag—C layer was deposited by magnetron sputtering technology. In 150 sccm of an Ar protective atmosphere, the temperature was 100° C., the magnetron source was an AlAg (1 at. % Ag) target, the power of the target was 2 kW, and the current of the target was 6 A. The bias voltage of the substrate was set to −100 V, 20 sccm of CH₄ was introduced, the gas pressure in the chamber was controlled to be 20 mTorr, and the deposition was carried out for 10 min. During the deposition of the coating, the substrate rotated at a constant speed in the chamber to obtain an as-deposited Al—Ag—C layer.
(4) The steps (2) and (3) were repeated 5 times to prepare an alternately laminated coating having 5 layers of Zr—C/Al—Ag—C.
(5) The Zr—C/Al—Ag—C alternately laminated coating was placed in an annealing furnace and kept at 500° C. for 360 min in an environment where a vacuum degree was lower than 2.0×10⁻⁵ Torr, to obtain a Zr₂AlC—Ag composite coating.

### Example 6

In this embodiment, the substrate was a pure titanium substrate, and the preparation method of the Ti—Al—N-based MAX phase-Ag composite coating on the surface of the substrate was as follows:
(1) The cleaned, oil-removed and dried substrate was put into the cavity. When the vacuum pressure in the cavity was below 2.0×10⁻⁵ Torr, 50 sccm of Ar gas was introduced into the vacuum chamber, the current of the linear anode ion source was set to 0.2 A, the bias voltage of the substrate was set to −150 V, and the ionized argon ion was used to etch the substrate for 50 min.
(2) A Ti—N layer was deposited by arc ion plating technology. In 200 sccm of an Ar protective atmosphere, the temperature was 150° C. A simple substance target of Ti element was mounted on the arc source as a Ti source. The power of the target was 1.5 kW, and the current of the target was 40 A. The bias voltage of the substrate was set to −50 V, 30 sccm of N₂ was introduced, the pressure in the chamber was controlled to be 20 mTorr, and the deposition was carried out for 5 min. During the deposition of the coating, the substrate rotated at a constant speed in the chamber to obtain an as-deposited Ti—N layer.
(3) An Al—Ag—N layer was deposited by magnetron sputtering technology. In 200 sccm of an Ar protective atmosphere, the temperature was 150° C., the magnetron source was an AlAg (7 at. % Ag) target, the power of the target was 3.5 kW, and the current of the target was 9 A. The bias voltage of the substrate was set to −50 V, 30 sccm of N₂ was introduced, the gas pressure in the chamber was controlled to be 20 mTorr, and the deposition was carried out for 5 min. During the deposition of the coating, the substrate rotated at a constant speed in the chamber to obtain an as-deposited Al—Ag—N layer.
(4) The steps (2) and (3) were repeated 10 times to prepare an alternately laminated coating having 10 layers of Ti—N/Al—Ag—N.
(5) The Ti—N/Al—Ag—N alternately laminated coating was placed in an annealing furnace and kept at 650° C. for 90 min in an environment where a vacuum degree was lower than 2.0×10⁻⁵ Torr, to obtain a Ti₂AlN—Ag composite coating.

### Comparative Example 1

In this comparative example, the substrate was an aluminium oxide substrate, and an Al target was used as a magnetron source to prepare a pure Cr₂AlC-based MAX phase coating. The specific process was as follows:
(1) The cleaned, oil-removed and dried substrate was put into the cavity. When the vacuum pressure in the cavity was below 3.0×10⁻⁵ Torr, 33.4 sccm of Ar gas was introduced into the vacuum chamber, the current of the linear anode ion source was set to 0.2 A, the bias voltage of the substrate was set to −200 V, and the ionized argon ion was used to etch the substrate for 30 min.
(2) A Cr—C layer was deposited by arc ion plating technology. In 200 sccm of an Ar protective atmosphere, the temperature was 150° C. A simple substance target of Cr element was mounted on the arc source as a Cr source. The power of the target was 1.0 kW, and the current of the target was 60 A. The bias voltage of the substrate was set to −150 V, 25 sccm of CH₄ was introduced, the pressure in the chamber was controlled to be 20 mTorr, and the deposition was carried out for 10 min. During the deposition of the coating, the substrate rotated at a constant speed in the chamber to obtain an as-deposited Cr—C layer.
(3) An Al—C layer was deposited by magnetron sputtering technology. In 200 sccm of an Ar protective atmosphere, the temperature was 150° C., the magnetron source was an Al target, the power of the target was 3.1 kW, and the current of the target was 7.0 A. The bias voltage of the substrate was set to −150 V, 25 sccm of CH₄ was introduced, the gas pressure in the chamber was controlled to be 20 mTorr, and the deposition was carried out for 10 min. During the deposition of the coating, the substrate rotated at a constant speed in the chamber to obtain an as-deposited Al—C layer.
(4) The steps (2) and (3) were repeated 6 times to prepare an alternately laminated coating having 6 layers of Cr—C/Al—C.
(5) The prepared Cr—C/Al—C alternately laminated coating was placed in an annealing furnace and kept at 700° C. for 120 min in an environment where a vacuum degree was less than 3.0×10⁻⁵ Torr, to obtain a Cr₂AlC coating.

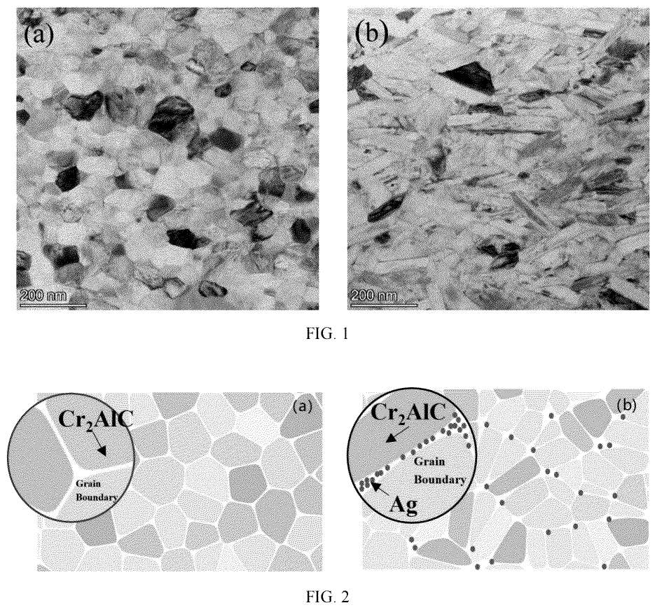

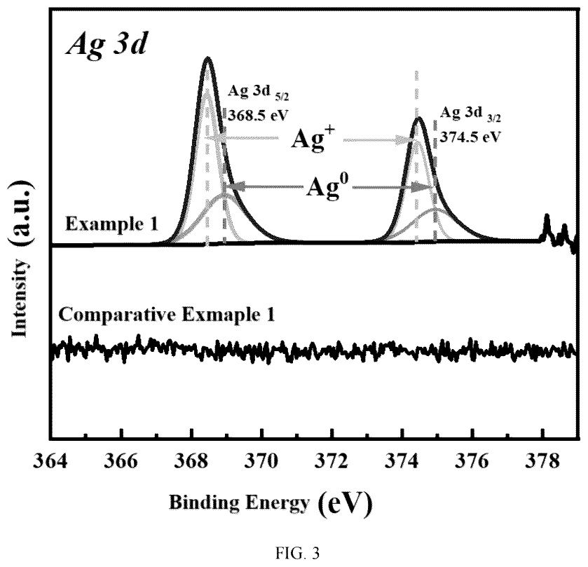

The coatings prepared in Example 1 and Comparative Example 1 were analyzed for microstructure by transmission electron microscopy (TEM), and the grain size and grain shape in the coatings were observed. The results were shown in FIG. 1, and the schematic diagram of the structure was shown in FIG. 2. It could be seen from the left part (a) of FIG. 1 and the left part (a) of FIG. 2 that the coating prepared in Comparative Example 1 was mainly composed of Cr₂AlC phase, and the equiaxed grains in the coating were uniform in size and closely arranged. It could be seen from the right part (b) of FIG. 1 and the right part (b) of FIG. 2 that the coating prepared in Example 1 was mainly composed of Cr₂AlC phase and Ag, and the original equiaxed MAX phase grains were converted into lath-like MAX phase grains due to the influence of Ag on the grain growth of the MAX phase grains, and at the same time, Ag was distributed at the grain boundary of the MAX phase.

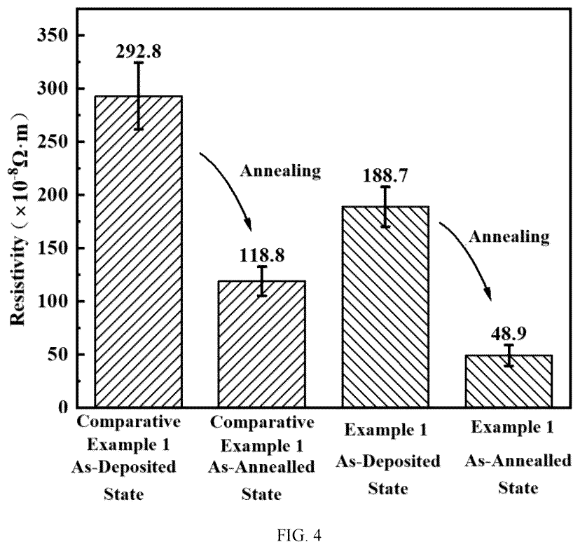

X-ray photoelectron spectroscopy (XPS) was used to analyze the chemical bond state of Ag on the surface of Example 1 and Comparative Example 1, and the results were shown in FIG. 3. It could be seen from FIG. 3 that the Ag 3d_{5/2} and Ag 3d_{3/2} peaks in Example 1 appeared at 374.5 eV and 368.5 eV in the figure, and at the same time, there was also an Ag⁺ peak, indicating that the Ag element in the coating existed in two forms, Ag⁺ and simple substance Ag. There was no peak in Comparative Example 1, indicating that there was no Ag element in the coating.

The resistivity of the coatings prepared in Example 1 and Comparative Example 1 before and after heat treatment was detected by using four-probe device, and the results were shown in FIG. 4. It could be seen from FIG. 4 that the resistivity of the as-deposited coating prepared in Comparative Example 1 was 292.8×10⁻⁸ Ω·m, the resistivity of the as-deposited coating prepared in Example 1 was 188.7×10⁻⁸ Ω·m, and the resistivity of the as-deposited coating in Example 1 was reduced by 35.5% compared with the as-deposited coating in Comparative Example 1; the resistivity of the as-annealed coating prepared in Comparative Example 1 was 118.8×10⁻⁸ Ω·m, the resistivity of the as-annealed coating prepared in Example 1 was 48.9×10⁻⁸ Ω·m, and the resistivity of the as-annealed coating in Example 1 was reduced by 58.8% compared with the as-annealed coating in Comparative Example 1. This proved that the continuous distribution structure of Ag at the MAX grain boundary provided a strong conductive path, and gave the coating excellent electrical conductivity property.

### Comparative Example 2

In this comparative example, the substrate was a high-temperature alloy substrate, and the preparation method of the Cr—Al—C-based MAX-Ag phase composite coating on the surface of the substrate was as follows:
(1) The cleaned, oil-removed and dried substrate was put into the cavity. When the vacuum pressure in the cavity was below 3.0×10⁻⁵ Torr, 33.4 sccm of Ar gas was introduced into the vacuum chamber, the current of the linear anode ion source was set to 0.2 A, the bias voltage of the substrate was set to −200 V, and the ionized argon ion was used to etch the substrate for 30 min.
(2) In 200 sccm of an Ar protective atmosphere, the temperature was 150° C. A simple substance target of Cr element was mounted on the arc source as a Cr source. The power of the target was 1.0 kW, and the current of the target was 60 A. The magnetron source was an AlAg (5 at. % Ag) target, the power of the target was 3.1 kW, and the current of the target was 7.0 A. The bias voltage of the substrate was set to −150 V, 25 sccm of CH₄ was introduced, the pressure in the chamber was controlled to be 20 m Torr, and the deposition was carried out for 120 min. During the deposition of the coating, the substrate rotated at a constant speed in the chamber to obtain an as-deposited Cr—Al—C—Ag layer.
(3) The as-deposited Cr—Al—C—Ag coating was placed in an annealing furnace and kept at 700° C. for 120 min in an environment where a vacuum degree was less than 3.0×10⁻⁵ Torr, to obtain a Cr₂AlC—Ag composite coating.

The coating prepared in this comparative example was tested for phase structure by X-ray diffractometer (XRD) with a scanning range of 5° to 90°. The results showed that the coating prepared in comparative example 1 consisted of Cr₂AlC phase and AlAg₃ phase, and Ag existed in the coating in the form of compound.

The resistivity of the coating prepared in Comparative Example 2 before and after heat treatment was detected by using four-probe device. The results showed that the resistivity of the as-deposited coating prepared in Comparative Example 2 was 196.6×10⁻⁸ Ω·m, and the resistivity of the as-annealed coating prepared in Comparative Example 2 was 69.2×10⁻⁸ Ω·m, the resistivity of the as-annealed coating in Comparative Example 2 was decreased by 64.8% compared with the as-deposited coating in Comparative Example 2. The resistivity of the as-annealed coating in Example 1 was decreased by 74.1% compared with the as-deposited coating in Example 1, and the resistivity of the as-annealed coating in Example 1 was decreased by 29.3% compared with the as-annealed coating in Comparative Example 2, indicating that the presence of Ag in the coating formed a new conductive path. Different from the electrically conductive mechanism of the coating in Comparative Example 2, the continuous distribution of Ag made the electrically conductive mechanism of the composite coating of the present disclosure behave as a metal-like property, and the electrical conductivity property was improved by about 30%.

### Comparative Example 3

In this comparative example, the substrate was an aluminium oxide substrate, and the magnetron source was an AlAg (20 at. % Ag) target. Except for the increase in the Ag content of the magnetron target, the other conditions were exactly the same as those of the above-mentioned Example 1. The specific process was as follows:
(1) The cleaned, oil-removed and dried substrate was put into the cavity. When the vacuum pressure in the cavity was below 3.0×10⁻⁵ Torr, 33.4 sccm of Ar gas was introduced into the vacuum chamber, the current of the linear anode ion source was set to 0.2 A, the bias voltage of the substrate was set to −200 V, and the ionized argon ion was used to etch the substrate for 30 min.
(2) A Cr—C layer was deposited by arc ion plating technology. In 200 sccm of an Ar protective atmosphere, the temperature was 150° C. A simple substance target of Cr element was mounted on the arc source as a Cr source. The power of the target was 1.0 kW, and the current of the target was 60 A. The bias voltage of the substrate was set to −150 V, 25 sccm of CH₄ was introduced, the pressure in the chamber was controlled to be 20 mTorr, and the deposition was carried out for 10 min. During the deposition of the coating, the substrate rotated at a constant speed in the chamber to obtain an as-deposited Cr—C layer.
(3) An Al—Ag—C layer was deposited by magnetron sputtering technology. In 200 sccm of an Ar protective atmosphere, the temperature was 150° C., the magnetron source was an AlAg (20 at. % of Ag) target, the power of the target was 3.1 kW, and the current of the target was 7.0 A. The bias voltage of the substrate was set to −150 V, 25 sccm of CH₄ was introduced, the gas pressure in the chamber was controlled to be 20 mTorr, and the deposition was carried out for 10 min. During the deposition of the coating, the substrate rotated at a constant speed in the chamber to obtain an as-deposited Al—Ag—C layer.
(4) The steps (2) and (3) were repeated 6 times to prepare an alternately laminated coating having 6 layers of Cr—C/Al—Ag—C.
(5) The Cr—C/Al—Ag—C alternately laminated coating was placed in an annealing furnace and kept at 700° C. for 120 min in an environment where a vacuum degree was lower than 3.0×10⁻⁵ Torr. After testing, no Cr₂AlC phase was formed in the coating. This was because the excessive amount of Ag affected the mutual diffusion of elements in the laminated structure.

Although the present disclosure is disclosed as above, the protection scope of the present disclosure is not limited thereto. Those skilled in the art can make various changes and modifications without departing from the spirit and scope of the present disclosure, and these changes and modifications will fall within the protection scope of the present disclosure.

1. A MAX-Ag electrically conductive composite coating, wherein the electrically conductive composite coating comprises a MAX phase and an Ag phase, the chemical formula of the MAX phase is Mₙ₊₁AXₙ, in the formula, M is selected from one of Cr, Ti, and Zr, A is an Al element, X is a C or N element, and n is an integer of 1 to 3, the MAX phase is in a lath-like structure, the Ag phase is in a nano-twinned structure, the Ag phase is aggregated at a grain boundary of the MAX phase, the electrically conductive composite coating as a whole is in an Ag-wrapped MAX phase structure, the Ag content in the electrically conductive composite coating is 1 at. % to 10 at. %, and the preparation method of the MAX-Ag electrically conductive composite coating comprises the following steps:
S1. providing a substrate, and sequentially performing mechanical polishing, ultrasonic cleaning and glow cleaning on the substrate;
S2. placing the substrate in a vacuum chamber, using a simple substance target of M element as an arc target, introducing a reaction gas for providing X element and an inert gas, and depositing an M-X layer by an arc ion plating technology;
S3. using the composite target of A element and Ag as a DC pulsed magnetron sputtering target, and depositing an A—Ag—X layer by the magnetron sputtering technology;
S4. repeating the steps S2 and S3 for 2 to 20 times to form an M-X/A—Ag—X alternately laminated coating;
S5. performing vacuum heat treatment on the alternately laminated coating obtained in the step S4 to obtain a MAX-Ag electrically conductive composite coating.

2. The MAX-Ag electrically conductive composite coating according to claim 1, wherein the MAX phase has a grain width of 10-90 nm and a grain length of 25-300 nm.

3. The MAX-Ag electrically conductive composite coating according to claim 2, wherein the MAX phase has a grain aspect ratio of between 2 and 7.

4. The MAX-Ag electrically conductive composite coating according to claim 1, wherein the Ag phase aggregated at the grain boundary of the MAX phase has a thickness of 1-20 nm.

5. The MAX-Ag electrically conductive composite coating according to claim 1, wherein the MAX phase is selected from one of Cr₂AlC, Cr₂AlN, Ti₂AlC, Ti₂AlN and Zr₂AlC.

6. A preparation method of the MAX-Ag electrically conductive composite coating according to claim 1, wherein the method comprises the following steps:
S1. providing a substrate, and sequentially performing mechanical polishing, ultrasonic cleaning and glow cleaning on the substrate;
S2. placing the substrate in a vacuum chamber, using a simple substance target of M element as an arc target, introducing a reaction gas for providing X element and an inert gas, and depositing an M-X layer by an arc ion plating technology;
S3. using the composite target of A element and Ag as a DC pulsed magnetron sputtering target, and depositing an A—Ag—X layer by the magnetron sputtering technology;
S4. repeating the steps S2 and S3 for 2 to 20 times to form an M-X/A—Ag—X alternately laminated coating;
S5. performing vacuum heat treatment on the alternately laminated coating obtained in the step S4 to obtain a MAX-Ag electrically conductive composite coating.

7. The preparation method of the MAX-Ag electrically conductive composite coating according to claim 6, wherein in the step S2, the substrate has a bias voltage of (−50)-(−200) V, the target-to-substrate distance between the substrate and the cathode arc target is 15-20 cm, the cathode arc target has a power of 1-3 kW and a current of 30-70 A, the reaction gas is introduced at a flow rate of 15-30 sccm, the inert gas is introduced at a flow rate of 150-200 sccm, and the deposition time is 5-30 min.

8. The preparation method of the MAX-Ag electrically conductive composite coating according to claim 6, wherein in the step S3, the substrate has a bias voltage of (−50)-(−200) V, the target-to-substrate distance between the substrate and the DC pulsed magnetron sputtering target is 10-15 cm, the DC pulsed magnetron sputtering target has a power of 2-3.5 kW, the reaction gas is introduced at a flow rate of 15-30 sccm, the inert gas is introduced at a flow rate of 150-200 sccm, and the deposition time is 5-30 min.

9. The preparation method of the MAX-Ag electrically conductive composite coating according to claim 6, wherein in the step S5, in the vacuum heat treatment, the vacuum degree is less than 2.0×10⁻³ Torr, the temperature is 500-750° C. and the time is 30-360 min.
